(19) United States
(12) Patent Application Publication
(10) Pub. No.: US 2016/0149042 A1
(43) Pub. Date: May 26, 2016

(54) SEMICONDUCTOR DEVICE AND METHOD OF MANUFACTURING THE SAME, AND DISPLAY UNIT AND ELECTRONIC APPARATUS

(71) Applicant: Sony Corporation, Tokyo (JP)

(72) Inventor: Ayumu Sato, Tokyo (JP)

(21) Appl. No.: 14/747,594

(22) Filed: Jun. 23, 2015

(30) Foreign Application Priority Data
Nov. 26, 2014 (JP) 2014-239153

(51) Int. Cl. H01L 29/786; H01L 29/10; H01L 27/12; H01L 21/441; H01L 29/66; H01L 21/02; H01L 21/465; H01L 29/24; H01L 49/02

(52) U.S. Cl. CPC H01L 29/7869; H01L 29/24; H01L 29/78696; H01L 29/1054; H01L 27/1255; H01L 28/40; H01L 29/66969; H01L 21/02565; H01L 21/465; H01L 21/441

(57) ABSTRACT

Provided is a semiconductor device, including a transistor in which an oxide semiconductor film, a gate insulating film, and a gate electrode are stacked in order, in which the oxide semiconductor film includes a first region portion and a second region portion. The oxide semiconductor film includes indium (In), zinc (Zn), and one or more of tin (Sn), gallium (Ga), and aluminum (Al). The first region portion is located, in a thickwise direction, in vicinity of an interface between the oxide semiconductor film and the gate insulating film, in the oxide semiconductor film. A composition ratio of the one or more of tin, gallium, and aluminum in the first region portion is higher than a composition ratio of the one or more of tin, gallium, and aluminum in the second region portion.

### CROSS REFERENCE TO RELATED APPLICATIONS

This application claims the benefit of Japanese Priority Patent Application JP 2014-239153 filed on Nov. 26, 2014, the entire contents of which are incorporated herein by reference.

### BACKGROUND

The present disclosure relates to a semiconductor device with use of an oxide semiconductor, and a display unit and an electronic apparatus including the semiconductor device.

A liquid crystal display unit or an organic EL (Electroluminescence) display unit that adopt an active matrix drive method uses a thin film transistor (TFT) as a drive element and allows a retention capacitor to retain charges corresponding to a signal voltage to write pictures. In the TFT, parasitic capacitance may be generated in an intersection region of a gate electrode and source/drain electrodes. If such parasitic capacitance should become large, the signal voltage may vary, causing degradation in image quality.

Thus, some methods have been proposed to reduce the parasitic capacitance in the intersection region of the gate electrode and the source/drain electrode in the TFT using, as a channel, an oxide semiconductor such as, but not limited to, zinc oxide (ZnO) or indium gallium zinc oxide (IGZO) (For example, refer to Japanese Unexamined Patent Application Publication No. 2007-220817, J. Park, et al., “Self-aligned top-gate amorphous gallium indium zinc oxide thin film transistors”, Applied Physics Letters, American Institute of Physics, 2008, vol. 93, 053501, and R. Hayashi, et al., “Improved Amorphous In—Ga—Zn—O TFTs”, SID 08 DIGEST, 2008, 42.1, p. 621-624).

In a transistor using the above-mentioned oxide semiconductor, as discussed by D. H. Kang, et al., “Threshold voltage dependence on channel length in amorphous-indium-gallium-zinc-oxide thin-film transistors”, Applied Physics Letters, American Institute of Physics, 2013, vol. 102, 083508, an effective channel length is known to decrease due to hydrogen diffusion from an edge of a channel region, and it is also known that a similar decrease in the effective channel length may occur due to oxygen desorption from the edge of the channel region. Japanese Unexamined Patent Application Publication No. 2013-179294 proposes a method to restrain oxygen desorption by forming a side wall having low oxygen permeability.

### SUMMARY

However, the method involving formation of the side wall that hardly transmits oxygen, as disclosed in Japanese Unexamined Patent Application Publication No. 2013-179294, may lead to a complicated structure of a semiconductor device, inhibiting micro-miniaturization. Also, its manufacturing method may become complex.

It is desirable to provide a semiconductor device that makes it possible to exhibit stable operation characteristics and to have a structure with good manufacturability, and a display unit and an electronic apparatus including the semiconductor device. It is also desirable to provide a method of manufacturing a semiconductor device that makes it possible to relatively easily manufacture the semiconductor device.

According to an embodiment of the present disclosure, there is provided a semiconductor device, including a transistor in which an oxide semiconductor film, a gate insulating film, and a gate electrode are stacked in order, in which the oxide semiconductor film includes a first region portion and a second region portion. The oxide semiconductor film includes indium (In), zinc (Zn), and one or more of tin (Sn), gallium (Ga), and aluminum (Al). The first region portion is located, in a thickwise direction, in vicinity of an interface between the oxide semiconductor film and the gate insulating film, in the oxide semiconductor film. A composition ratio of the one or more of tin, gallium, and aluminum in the first region portion is higher than a composition ratio of the one or more of tin, gallium, and aluminum in the second region portion.

According to an embodiment of the present disclosure, there is provided a display unit provided with a display element and a semiconductor device configured to drive the display element. The semiconductor device includes a transistor in which an oxide semiconductor film, a gate insulating film, and a gate electrode are stacked in order, in which the oxide semiconductor film includes a first region portion and a second region portion. The oxide semiconductor film includes indium (In), zinc (Zn), and one or more of tin (Sn), gallium (Ga), and aluminum (Al). The first region portion is located, in a thickwise direction, in vicinity of an interface between the oxide semiconductor film and the gate insulating film, in the oxide semiconductor film. A composition ratio of the one or more of tin, gallium, and aluminum in the first region portion is higher than a composition ratio of the one or more of tin, gallium, and aluminum in the second region portion.

According to an embodiment of the present disclosure, there is provided an electronic apparatus provided with a display unit including a display element and a semiconductor device configured to drive the display element. The semiconductor device includes a transistor in which an oxide semiconductor film, a gate insulating film, and a gate electrode are stacked in order, in which the oxide semiconductor film includes a first region portion and a second region portion. The oxide semiconductor film includes indium (In), zinc (Zn), and one or more of tin (Sn), gallium (Ga), and aluminum (Al). The first region portion is located, in a thickwise direction, in vicinity of an interface between the oxide semiconductor film and the gate insulating film, in the oxide semiconductor film. A composition ratio of the one or more of tin, gallium, and aluminum in the first region portion is higher than a composition ratio of the one or more of tin, gallium, and aluminum in the second region portion.

According to an embodiment of the present disclosure, there is provided a method of manufacturing a semiconductor device, including: forming, on a substrate, an oxide semiconductor film including indium (In), zinc (Zn), and one or more of tin (Sn), gallium (Ga), and aluminum (Al); and stacking a gate insulating film and a gate electrode in order on the oxide semiconductor film to form a transistor, after increasing a composition ratio of the one or more of tin, gallium, and aluminum in vicinity of an upper surface of the oxide semiconductor film.

In the semiconductor device and the manufacturing method thereof, and the display unit and the electronic apparatus according to the above-described embodiments of the present disclosure, in the oxide semiconductor film, the composition ratio of the one or more of tin, gallium, and aluminum in the vicinity of the interface between the oxide semiconductor film and the gate insulating film is high. This allows for low oxygen permeability in the vicinity of the interface in the oxide semiconductor film.

According to the semiconductor device and the manufacturing method thereof in the above-described embodiments of the present disclosure, it is possible to sufficiently obtain stable operation characteristics and good manufacturability. It is therefore possible for the display unit and the electronic apparatus including the semiconductor device to exhibit good display performance. It is to be noted that effects of the present disclosure are not limited to those described here, but may be any of effects described in the followings.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view illustrating a configuration of a semiconductor device according to a first embodiment of the present disclosure.

FIG. 2 is a cross-sectional view illustrating, in an enlarged manner, a main part of the semiconductor device illustrated in FIG. 1.

FIG. 3A is a cross-sectional view illustrating a process in a method of manufacturing the semiconductor device illustrated in FIG. 1.

FIG. 3B is a cross-sectional view illustrating a process following FIG. 3A.

FIG. 3C is a cross-sectional view illustrating a process following FIG. 3B.

FIG. 3D is a cross-sectional view illustrating a process following FIG. 3C.

FIG. 3E is a cross-sectional view illustrating a process following FIG. 3D.

FIG. 3F is a cross-sectional view illustrating a process following FIG. 3E.

FIG. 3G is a cross-sectional view illustrating a process following FIG. 3F.

FIG. 3H is a cross-sectional view illustrating a process following FIG. 3G.

FIG. 3I is a cross-sectional view illustrating a process following FIG. 3H.

FIG. 4A is a cross-sectional view illustrating a process as a modification example of the method of manufacturing the semiconductor device illustrated in FIG. 1.

FIG. 4B is a cross-sectional view illustrating a process following FIG. 4A.

FIG. 5 is a cross-sectional view illustrating a configuration of a semiconductor device according to a second embodiment of the present disclosure.

FIG. 6 is a cross-sectional view illustrating a configuration of a first display unit according to a third embodiment of the present disclosure.

FIG. 7 is a diagram illustrating an overall configuration, including peripheral circuits, of the display unit illustrated in FIG. 6.

FIG. 8 is a diagram illustrating a circuit configuration of a pixel illustrated in FIG. 7.

FIG. 9 is a cross-sectional view illustrating a configuration of a second display unit according to the third embodiment of the present disclosure.

FIG. 10 is a cross-sectional view illustrating a configuration of a third display unit according to the third embodiment of the present disclosure.

FIG. 11 is a plan view schematically illustrating a configuration of a module including the display unit according to the above-mentioned third embodiment.

FIG. 12 is a perspective view illustrating an appearance of a smart phone as an application example of the display unit according to the above-mentioned third embodiment.

FIG. 13 is a perspective view illustrating an appearance of a television device as an application example of the display unit according to the above-mentioned third embodiment.

FIG. 14 is a characteristic diagram illustrating comparison between composition ratios of surfaces of oxide semiconductor films of experimental examples 1-1 and 1-2.

FIG. 15 is a characteristic diagram illustrating comparison between phosphorus 2 p peak intensity in the surfaces of the oxide semiconductor films of the experimental examples 1-1 and 1-2.

FIG. 16 is a characteristic diagram illustrating relation between heat treatment time and an amount of change in an effective channel length, examined concerning experimental examples 2-1 and 2-2.

### DETAILED DESCRIPTION

In the following, some embodiments of the present disclosure will be described in detail with reference to the accompanying drawings. It is to be noted that description will be made in the following order.

1. First Embodiment (a semiconductor device in which a first region portion in an oxide semiconductor film extends over an entire interface between the oxide semiconductor film and a gate insulating film)

2. Modification Example of First Embodiment (a semiconductor device)

3. Second Embodiment (a semiconductor device in which the first region portion in the oxide semiconductor film is located in vicinity of a periphery of a channel region)

4. Third Embodiment (a display unit including the above-mentioned semiconductor device)
4.1. Organic EL display unit
4.2. Liquid crystal display unit
4.3. Electronic paper

5. Application Examples (a module including the above-mentioned display unit, and electronic apparatuses)

6. Experimental Examples

### 1. First Embodiment

### Configuration of Semiconductor Device 1

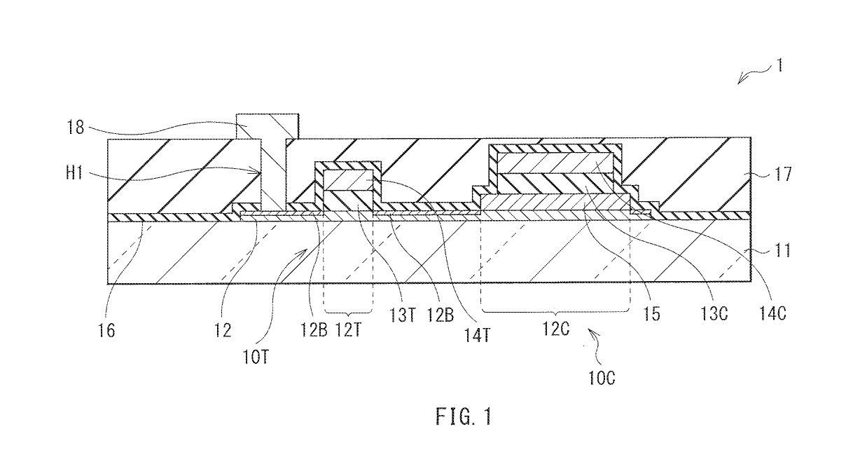

Description will now be given on a semiconductor device 1 according to a first embodiment of the present disclosure with reference to FIG. 1. The semiconductor device 1 may be used as a drive element in, for example, an active-matrix organic EL display unit or liquid crystal display unit.

The semiconductor device 1 may include a substrate 11, a transistor 10T, and a retention capacitor 10C. The transistor 10T and the retention capacitor 10C may be provided in a side-by-side relationship on the substrate 11. The substrate 11, the transistor 10T, and the retention capacitor 10C may be covered by a high resistance film 16 except for a part or some parts. The high resistance film 16 may be covered by an insulating film 17.

The transistor 10T may be a thin film transistor (TFT) having a top-gate structure (a stagger structure). The transistor 10T includes an oxide semiconductor film 12, a gate insulating film 13T, and a gate electrode 14T that are stacked in order on the substrate 11. The transistor 10T may further include a source/drain electrode 18 in a region of an upper surface of the insulating film 17. The source/drain electrode 18 may be electrically connected to a low resistance region 12B of the oxide semiconductor film 12 through a contact hole H1. The contact hole H1 may be provided so as to go through both the high resistance film 16 and the insulating film 17 in a thickwise direction.

(Transistor 10T)

The substrate 11 may be configured of a plate member such as, but not limited to, quartz, glass, silicon, or a resin (plastic) film. A low-cost resin film may be used since the oxide semiconductor film 12 may be deposited without heating the substrate 11 by a sputter method, which will be described later. Non-limited examples of resin materials may include PET (polyethylene terephthalate) and PEN (polyethylene naphthalate). In addition to these, a metal substrate such as, but not limited to, stainless steel (SUS) may be used according to purposes. It is to be noted that, in a case of using a metal substrate, it is desirable that its upper surface be coated with an insulating layer.

The oxide semiconductor film 12 may be formed in an island shape in a selective region over the substrate 11. The oxide semiconductor film 12 may have a function of an active layer of the transistor 10T. A thickness of the semiconductor film 12 may be, for example, 20 nm to 50 nm both inclusive. The oxide semiconductor film 12 may include, as a main component, an oxide including indium (In), zinc (Zn), and one or more of tin (Sn), gallium (Ga), and aluminum (Al). Specific but non-limited examples may include indium tin zinc oxide (ITZO), indium gallium oxide (IGO), indium tin oxide (ITO), aluminum tin zinc oxide (ATZO), zinc tin oxide (ZTO), indium tin zinc aluminum oxide (ITZAO), and indium gallium zinc oxide (IGZO).

The oxide semiconductor film 12 may include a channel region 12T that face the gate electrode 14T in an upper level. In other words, the gate insulating film 13T and the gate electrode 14T may be stacked in order on the channel region 12T of the oxide semiconductor film 12, and may have a same planar shape as that of the channel region 12T, attaining a self-aligned structure. The oxide semiconductor film 12 may further include a pair of low resistance regions 12B (source/drain regions) having lower electrical resistivity than that of the channel region 12T. The pair of low resistance regions 12B may be provided in a side-by-side relationship with the channel region 12T in between. The low resistance regions 12B may be provided in part in the thickwise direction, extending from a surface (an upper surface) of the oxide semiconductor film 12. The low resistance regions 12B may be formed by, for example, diffusing a metal (dopant) by reaction of an oxide semiconductor material with a metal such as, but not limited to, aluminum (Al). As mentioned above, the source/drain electrode 18 may be electrically connected to the low resistance region 12B through the contact hole H1.

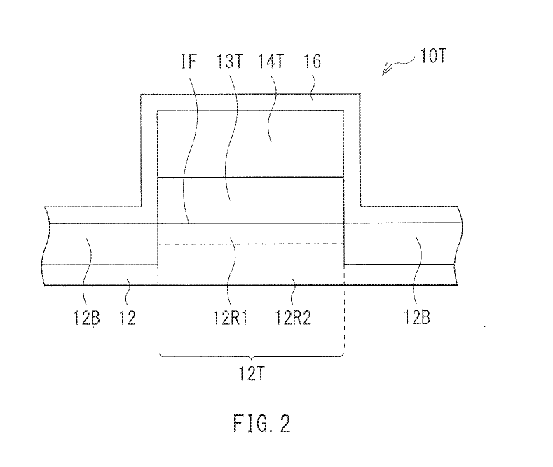

FIG. 2 illustrates a cross-section of the transistor 10T in an enlarged manner. The oxide semiconductor film 12 includes a first region portion 12R1 and a second region portion 12R2. The first region portion 12R1 is located, in the thickwise direction, in vicinity of an interface IF between the oxide semiconductor film 12 and the gate insulating film 13T, in at least the channel region 12T. The second region portion 12R2 may occupy other regions. A composition ratio of the one or more of tin, gallium, and aluminum in the first region portion 12R1 is higher than a composition ratio of the one or more of tin, gallium, and aluminum in the second region portion 12R2. Accordingly, a composition ratio of indium in the first region portion 12R1 is lower than a composition ratio of indium in the second region portion 12R2. Moreover, the first region portion 12R1 may extend, for example, over the entire channel region 12T of the oxide semiconductor film 12 in an in-plane direction. It is to be noted that the term ‘in vicinity of the interface IF’ refers to a region extending from a thickwise center position of the oxide semiconductor film 12 to the interface IF. The first region portion 12R1 may be preferably included in a thickwise range of, for example, 3 nm or less extending from the interface IF.

The gate electrode 14T may be provided on the channel region 12T with the gate insulating film 13T in between. The gate electrode 14T and the gate insulating film 13T may have a same shape in planar view.

The gate insulating film 13T may have a thickness of, for example, about 300 nm and may be configured of a single-layer film made of one of a silicon oxide film (SiO), a silicon nitride film (SiN), a silicon oxynitride film (SiON), an aluminum oxide film (AlO) and the like, or a stacked film made of two or more thereof. For the gate insulating film 13T, a material that hardly reduces the oxide semiconductor film 12, for example, a silicon oxide film or an aluminum oxide film may be preferably used.

The gate electrode 14T is configured to control a carrier density in the oxide semiconductor film 12 (the channel region 12T) with a gate electrode (Vg) applied to the transistor 10T. The gate electrode 14T also has a function as a wiring to supply potentials. The gate electrode 14T may be configured of, for example, a single substance of one of molybdenum (Mo), titanium (Ti), aluminum, silver (Ag), neodymium (Nd) and copper (Cu), or an alloy thereof. The gate electrode 14T may have a multi-layered structure using a plurality of single substances or alloys. The gate electrode 14T may be configured of, for example, titanium, aluminum, and molybdenum stacked in this order from the oxide semiconductor film 14 side. The gate electrode 14T may be preferably configured of a low resistance metal such as, but not limited to, aluminum and copper. On a layer made of a low resistance metal (a low resistance layer), a layer made of, for example, titanium or molybdenum (a barrier layer) may be stacked. Alternatively, an alloy including a low resistance metal, for example, an alloy of aluminum and neodymium (Nd) (Al—Nd alloy) may be used. The gate electrode 14T may be configured of a transparent conductive film such as, but not limited to, ITO. A thickness of the gate electrode 14T may be, for example, 10 nm to 500 nm both inclusive.

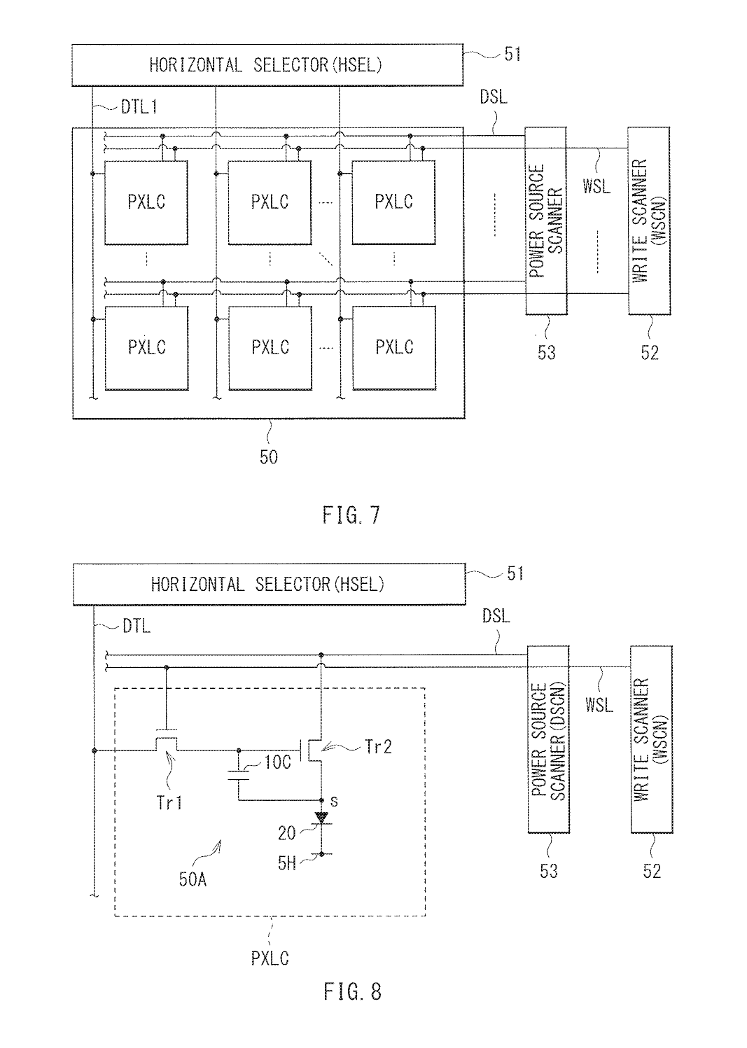

The high resistance film 16 may be provided between the gate electrode 14T and the insulating film 17, and between the oxide semiconductor film 12 (the low resistance region 12B) and the insulating film 17. The high resistance film 16 may cover an end surface of the gate electrode 14T, an end surface of the gate insulating film 13T, and an end surface of the oxide semiconductor film 12. The high resistance film 16 may also cover the retention capacitor 10C. The high resistance film 16 is remainder of a metal film (a metal film 16A in FIG. 7B, which will be described later) that serves as a supply source of a metal to be diffused in the low resistance region 12B of the oxide semiconductor film 12 and turns into an oxide film in a manufacturing process, which will be described later. The high resistance film 16 may be in contact with the low resistance region 12B of the oxide semiconductor film 12. It is to be noted that an insulating film having higher barrier property, for example, an aluminum oxide film, may be provided on the remainder oxide film to constitute the high resistance film 16.

The high resistance film 16 may have a thickness of, for example, 20 nm or less, and may be configured of aluminum oxide, titanium oxide, indium oxide, tin oxide, or the like. The high resistance film 16 may be a stack of a plurality of oxide films. When an insulating film having high barrier property is stacked on the high resistance film 16, a total sum of thicknesses thereof may be, for example, about 50 nm. The high resistance film 16 may have a barrier function, that is, a function of reducing influences of oxygen or moisture that may change electrical characteristics of the oxide semiconductor film 12 in the transistor 10T, as well as the above-mentioned function in the manufacturing processes. Accordingly, providing the high resistance film 16 makes it possible to stabilize the electrical characteristics of the transistor 10T and the retention capacitor 10C, and to further enhance effects of the insulating film 17.

The insulating film 17 may be provided on the high resistance film 16. The insulating film 17 may extend to an outside of the oxide semiconductor film 12 to cover the gate electrode 14T and the oxide semiconductor film 12, similarly to the high resistance film 16. The insulating film 17 may be configured of, for example, an organic material such as, but not limited to, an acrylic resin, polyimide, and siloxane, or an inorganic material such as, but not limited to, a silicon oxide film, a silicon nitride film, a silicon oxynirtide film, and aluminum oxide. The insulating film 17 may be a stack made of these organic materials and inorganic materials. The insulating film 17 including an organic material may be easily thickened to a thickness of, for example, about 2 μm. The insulating film 17 thus thickened may sufficiently cover level differences such as between the gate insulating film 13T and the gate electrode 14T, providing sufficient insulation.

The source/drain electrode 18 may be provided in a patterned shape on the insulating film 17. The source/drain electrode 18 may be connected to the low resistance region 12B of the oxide semiconductor film 12 through the contact hole H1 that goes through the insulating film 17 and the high resistance film 16. The source/drain electrode 18 may be preferably provided so as to avoid a region directly above the gate electrode 14T. This makes it possible to prevent generation of parasitic capacitance in an intersection region of the gate electrode 14T and the source/drain electrode 18. The source/drain electrode 18 may have a thickness of, for example, about 500 nm, and may be configured of a low resistance metal material such as, but not limited to, aluminum and copper. Alternatively, the source/drain electrode 18 may be a stacked film of a low resistance layer made of a low resistance metal material such as aluminum and copper, and a barrier layer made of molybdenum or the like. The source/drain electrode 18 configured of such a stacked film allows for drive with little wiring delay. An alloy of aluminum and neodymium may be provided in an uppermost layer of the source/drain electrode 18.

(Retention Capacitor 10C)

The retention capacitor 10C may be, for example, a capacitive element configured to retain charges in a pixel circuit 50A, which will be described later. The retention capacitor 10C may be provided on the oxide semiconductor film 12 extending from the transistor 10T, and may have a structure in which an oxide conductive film 15, a capacitor insulating film 13C and a capacitor electrode 14C are stacked in an order of closeness to the oxide semiconductor film 12. In other words, in a region in which the retention capacitor 10C is formed, the oxide conductive film 15 is in contact with an upper surface of the oxide semiconductor film 12. In this way, the oxide conductive film 15 is provided separately from the oxide semiconductor film 12 so as to serve as one of electrodes of the retention capacitor 10C. This makes it possible to retain desired capacitance stably regardless of magnitude of an applied voltage.

The oxide conductive film 15 may be configured of an oxide semiconductor material. For a material of the oxide conductive film 15, a material may be preferably used that includes at least one same element as a constituent material of the oxide semiconductor film 12. When the oxide semiconductor film 12 is configured of indium tin zinc oxide (ITZO), indium gallium oxide (IGO), indium tin oxide (ITO), aluminum tin zinc oxide (ATZO), or zinc tin oxide (ZTO), the oxide conductive film 15 may be configured with use of, for example, indium gallium zinc oxide (IGZO) or indium zinc oxide (IZO, registered trademark). A thickness of the oxide conductive film 15 may be, for example, 20 nm to 200 nm both inclusive. Conductivity of the oxide conductive film 15 may be, for example, 1×10 S/cm to 1×10⁴ S/cm both inclusive.

The oxide conductive film 15 may be provided in a selective region on the oxide semiconductor film 12. An entire lower surface of the oxide conductive film 15 (a surface opposite to a surface facing the capacitor electrode 14C) may be in contact with the oxide semiconductor film 12.

The capacitor insulating film 13C may be configured of, for example, an inorganic insulating material. The capacitor insulating film 13C may be integrally formed with the gate insulating film 13T, may be made of a same material as that of the gate insulating film 13T, and may have a same thickness as that of the gate insulating film 13T. Also, the capacitor electrode 14C may be formed in a same manufacturing process as that of the gate electrode 14T, may be configured of a same material as that of the gate electrode 14T, and may have a same thickness. The capacitor electrode 14C and the capacitor insulating film 13C may have a same shape in planar view, and may be stacked at a same location on a substrate. It is to be noted that the capacitor insulating film 13C and the gate insulating film 13T may be formed in separate processes, may be configured of different materials, or may have different thicknesses. The same may apply to relation between the capacitor electrode 14C and the gate electrode 14T.

[Method of Manufacturing Semiconductor Device 1]

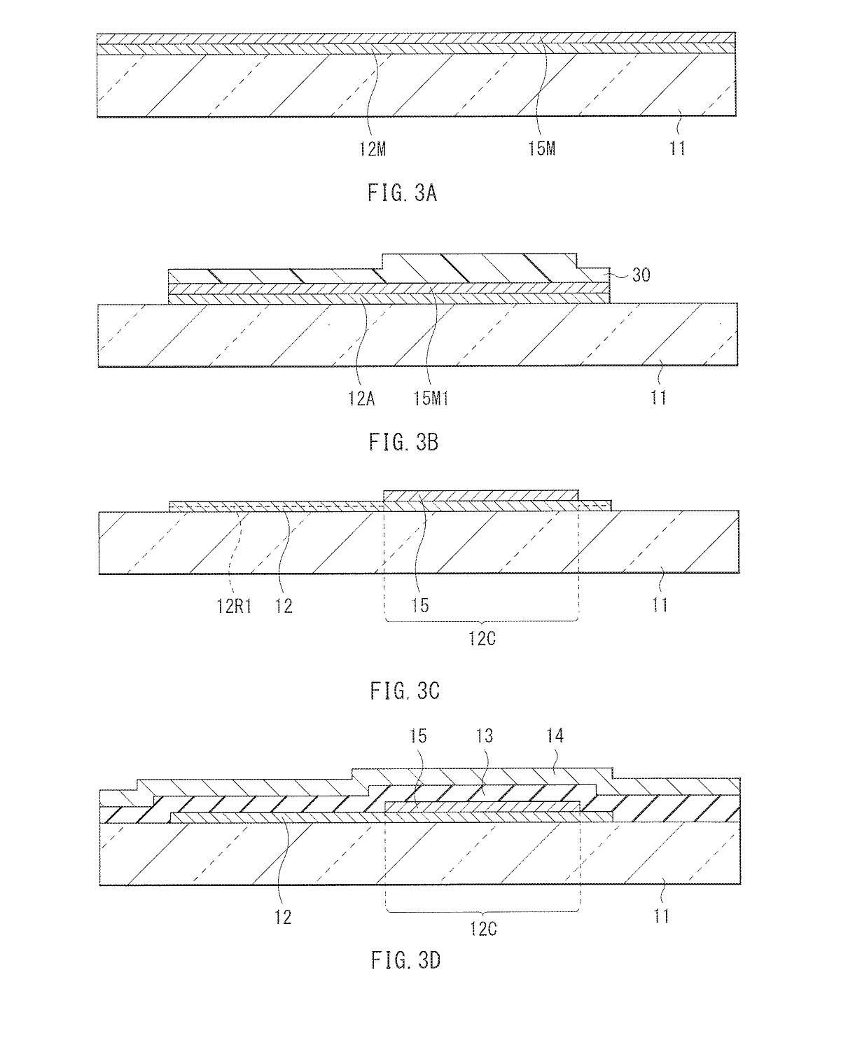

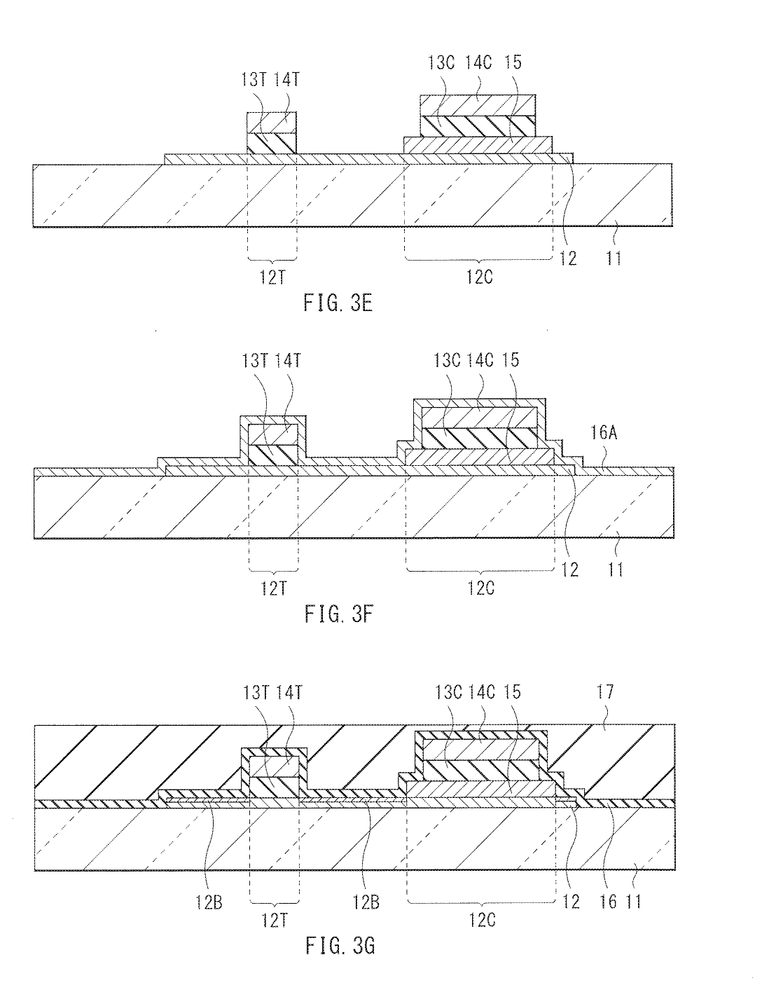

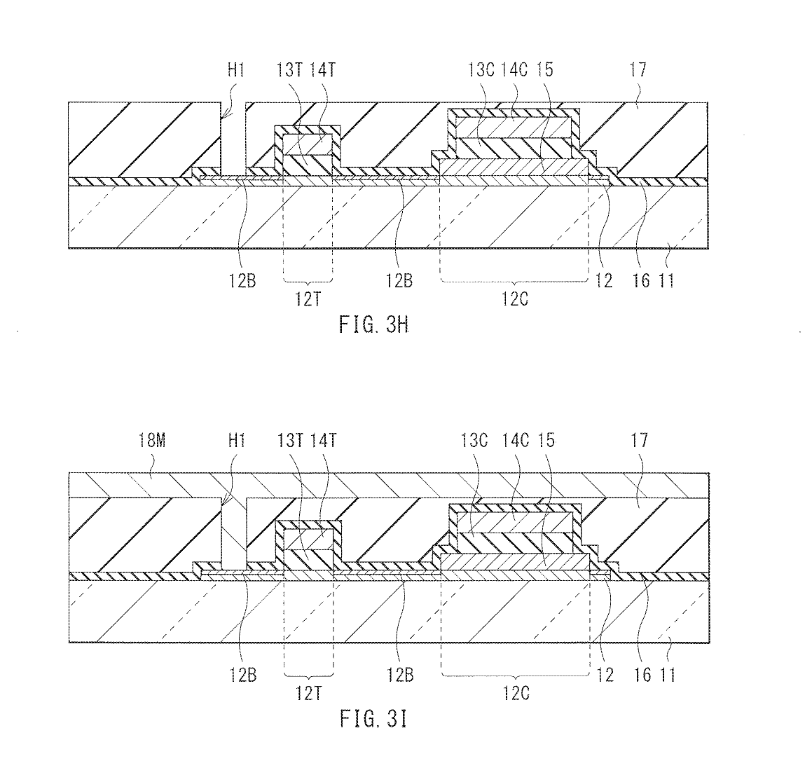

Next, description will be made on a method of manufacturing the semiconductor device 1 with reference to FIGS. 3A to 31 in addition to FIGS. 1 and 2. FIGS. 3A to 31 each illustrate, in cross-section, part of the method of manufacturing the semiconductor device 1.

First, referring to FIG. 3A, a semiconductor material film 12M is deposited over an entire surface of the substrate 11. The semiconductor material film 12M may be configured of the above-described constituent material of the oxide semiconductor film 12, for example, ITZO. The semiconductor material film 12M may be deposited by, for example, a sputtering method. At this occasion, as a target, ceramic having a same composition as that of the constituent material of the oxide semiconductor film 12 as an object to be deposited may be used. Since a carrier density in the oxide semiconductor highly depends on an oxygen partial pressure at the time of sputtering, the oxygen partial pressure may be controlled so as to obtain desired transistor characteristics. Further, an oxide conductive material film 15M is deposited by, for example, a sputtering method on an entire surface of the semiconductor material film 12M. The oxide conductive material film 15M may be configured of the above-described constituent material of the oxide conductive film 15, for example, IZO having conductivity of 1×10² S/cm or more. Here, the semiconductor material film 12M and the oxide conductive material film 15M each may be deposited to a thickness of, for example, 50 nm.

Next, referring to FIG. 3B, a resist 30 is formed on the oxide conductive material film 15M by, for example, photolithography using a half tone mask so as to have different thicknesses according to location in a plane. In the resist 30, a thickness of a region in which the oxide conductive film 15 is formed (a region including a region in which the retention capacitor 10C is formed) may be larger than those of other regions. Next, the semiconductor material film 12M is etched using, for example, an etchant including fluorine, such as buffered hydrofluoric acid, or oxalic acid, to form a semiconductor material film 12A. The etchant used in this etching process (a first etchant) is configured to solve the oxide conductive material film 15M as well as the semiconductor material film 12M. Thus, an oxide conductive material film 15M1 is formed that has a same shape as that of the semiconductor material film 12A in planar view.

Subsequently, an entire surface of the resist 30 may be ashed with a dry etching device or the like using, for example, an oxygen gas, to remove a thin portion of the resist 30. In other words, a region in which the oxide conductive film 15 is formed may be selectively covered by the resist 30. Thereafter, referring to FIG. 3C, wet etching may be carried out using an etchant including phosphoric acid, for example, a mixed liquid of phosphoric acid, nitric acid, and acetic acid (a second etchant), to selectively remove a portion exposed from the resist 30 of the oxide conductive material film 15M1. Thus, the oxide conductive film 15 is formed in a desired shape. At this occasion, the etching treatment with the mixed liquid of phosphoric acid, nitric acid, and acetic acid causes partial removal of indium (In) from a surface of the semiconductor material film 12A, leading to a decrease in a composition ratio of indium (In). This results in a relative increase in a composition ratio of a strongly oxidative element (that is, tin (Sn) when the oxide semiconductor film 12 is made of ITZO). In this way, the oxide semiconductor film 12 including the first region portion 12R1 is obtained. It is to be noted that phosphorus (P) included in the mixed liquid of phosphoric acid, nitric acid, and acetic acid used in the etching treatment remains in the first region portion 12R1. After forming the oxide conductive film 15, the resist 30 may be removed.

Next, referring to FIG. 3D, an insulating film 13 and a conductive film 14 are deposited in this order over the entire surface of the substrate 11. The insulating film 13 may be configured of, for example, a silicon oxide film, an aluminum oxide film, or the like with a thickness of 200 nm. The conductive film 14 may be configured of a metal material such as, but not limited to, molybdenum, titanium, aluminum, or the like with a thickness of 500 nm. The insulating film 13 may be deposited by, for example, a plasma CVD (chemical vapor deposition) method. The insulating film 13 made of a silicon oxide film may be formed by a reactive sputtering method as well as a plasma CVD method. In a case with use of an aluminum oxide film for the insulating film 13, an atomic layer deposition method may be also used as well as a reactive sputtering method and a CVD method. The conductive film 14 may be formed by, for example, a sputtering method.

After forming the conductive film 14, the conductive film 14 is processed in a desired shape by, for example, photolithography and etching. Specifically, the gate electrode 14T and the capacitor electrode 14C are formed on their respective, selective regions (that is, a region corresponding to the channel region 12T and a region corresponding to a contact region 12C) over the oxide semiconductor film 12. Next, the insulating film 13 is etched with use of the gate electrode 14T and the capacitor electrode 14C as masks, thereby patterning the gate insulating film 13T and the capacitor insulating film 13C (refer to FIG. 3E). The gate insulating film 13T and the capacitor insulating film 13C are in same shapes in planar view as those of the gate electrode 14T and the capacitor electrode 14T, respectively. The capacitor insulating film 13C and the capacitor electrode 14C of the retention capacitor 10C may be formed using different materials from those of the insulating film 13 and the conductive film 14 after forming the gate electrode 14T and the gate insulating film 13T.

Subsequently, referring to FIG. 3F, a metal film 16A is formed by, for example, a sputtering method over the entire surface of the substrate 11. The metal film 16A may be configured of a metal that reacts with oxygen at relatively low temperatures, for example, aluminum, titanium, tin, indium, or the like. The metal film 16A may be formed with a thickness of, for example, 5 nm to 10 nm both inclusive. The metal film 16A may be formed in contact with the oxide semiconductor film 12 except for portions in which the gate electrode 14T and the capacitor electrode 14C are formed. After forming the metal film 16A, an insulating film (not illustrated) having high barrier property may be stacked on the metal film 16A. As such insulating film, for example, an aluminum oxide film with a thickness of 50 nm may be formed by a sputtering method or an atomic layer deposition method.

Next, heat treatment is carried out in an oxygen atmosphere at a temperature of, for example, about 200° C. to oxidize the metal film 16A. In this way, as illustrated in FIG. 3G, the high resistance film 16 made of a metal oxide film is formed. At this occasion, the low resistance region 12B (including source/drain regions) is formed as well, in part in the thickwise direction (an upper part) of a region except for the channel region 12T and the contact region 12C in the oxide semiconductor film 12. Since part of oxygen included in the oxide semiconductor film 12 is used in oxidation reaction of the metal film 16A, a decrease in an oxygen concentration in the oxide semiconductor film 12 occurs, from a surface (an upper surface) side that is in contact with the metal film 16A, accompanying progress of oxidation of the metal film 16A. In the meanwhile, a metal such as aluminum diffuses from the metal film 16A in the oxide semiconductor film 12. The metal element serves as a dopant to lower resistance of a region on the upper surface side of the oxide semiconductor film 12 that is in contact with the metal film 16A. Thus, the low resistance region 12B is formed that has lower electrical resistance than those of the channel region 12T and the contact region 12C. The low resistance region 12B may be used as a source region and a drain region in the transistor 10T. It is to be noted that, although reaction of a metal with an oxide semiconductor has been utilized in the foregoing, source/drain regions having low resistance may be formed by a method using plasma, or by hydrogen diffusion from a silicon nitride film by a plasma CVD method, or the like.

As the heat treatment of the metal film 16A, for example, as mentioned above, heat treatment at a temperature of about 200° C. in an oxygen-including atmosphere may be preferable. At this occasion, annealing may be carried out in an oxidizing gas atmosphere including oxygen or the like makes it possible to restrain the oxygen concentration in the low resistance region 12B from becoming too low, allowing for sufficient oxygen supply to the oxide semiconductor film 12. This makes it possible to eliminate a subsequent annealing process, leading to simplification of manufacturing processes.

The high resistance film 16 may be formed, instead of the above-described annealing process, by forming the metal film 16A on the substrate 11 while setting a temperature of the substrate 11 to a relatively high temperature. For example, in a process illustrated in FIG. 3F, the metal film 16A may be deposited while keeping the temperature of the substrate 11 about 200° C. In this way, resistance of a predetermined region of the oxide semiconductor film 12 may be lowered without a subsequent heat treatment. In this case, it is possible to lower a carrier density of the oxide semiconductor film 12 to a sufficient level as a transistor.

The metal film 16A may be preferably deposited with a thickness of 10 nm or less, as described above. When the thickness of the metal film 16A is 10 nm or less, it is possible to oxidize the metal film 16A completely by the heat treatment (to form the high resistance film 16). If the metal film 16A is not oxidized sufficiently, the non-oxidized metal film 16A may be removed by etching. This is because, if the metal film 16A that is not oxidized sufficiently should remain on the gate electrode 14T and the capacitor electrode 14C, there may be possibility of occurrence of leak currents. When the metal film 16A is oxidized enough to form the desired high resistance film 16, such removal process becomes unnecessary, leading to simplification of manufacturing processes. It is to be noted that, when the metal film 16A is deposited with a thickness of 10 nm or less, a thickness of the high resistance film 16 after heat treatment may be about 20 nm or less.

As a method of oxidizing the metal film 16A, the following methods may be used as well as the above-mentioned heat treatment: a method of oxidizing by a vapor atmosphere; and plasma oxidization. In particular, plasma oxidization may have advantages as follows. The insulating film 17 may be formed by, for example, a plasma CVD method after formation of the high resistance film 16 (refer to FIG. 3G). At this occasion, it is possible to perform plasma oxidization treatment on the metal film 16A and then deposit the insulating film 17 successively (continuously). Accordingly, there is an advantage that no additional process is necessary. Plasma oxidization may preferably involve, for example, performing treatment with plasma generated in a gas atmosphere including oxygen, such as a mixed gas of oxygen and oxygen dinitride or the like, while setting the temperature of the substrate 11 to about 200° C. to 400° C. both inclusive. Such a process allows for formation of the high resistance film 16 having a function of reducing influences of oxygen or moisture (having good barrier property). Moreover, in order to attain a sufficient protective film function, it is preferable that an insulating film having high barrier property such as aluminum oxide be formed as a protective film successively after forming the metal film. For example, an aluminum oxide film with a thickness of about 50 nm may be formed continuously on the metal film. This makes it possible to further enhance the sufficient protective function. It is to be noted that the high resistance film 16 may be formed on the gate insulating film 13T, on the gate electrode 14T, and so forth, as well as on the low resistance region 12B in the oxide semiconductor film 12. Since the high resistance film 16 is a sufficiently-oxidized metal oxide film, the high resistance film 16 is unlikely to cause leak currents even when the high resistance film 16 remains without being removed by etching.

After forming the high resistance film 16, referring to FIG. 3G, the insulating film 17 is formed over the entire surface of the high resistance film 16. When the insulating film 17 includes an inorganic insulating material, a plasma CVD method, a sputtering method, or an atomic layer deposition method may be used, for example. When the insulating film 17 includes an organic insulating material such as acryl, polyimide, siloxane, or the like, a coating method such as, but not limited to, a spin coating method, a slit coating method may be used. A coating method allows for easy formation of the insulating film 17 thickend to about 2 μm. In another alternative, a stacked film of a silicon oxide film and an organic film may be formed as the insulating film 17.

Subsequently, referring to FIG. 3H, exposure and development processes are carried out to form, at a predetermined position, the contact hole H1 that goes through the insulating film 17 and the high resistance film 16. When a photosensitive resin is used for the insulating film 17, exposure and development may be carried out with the photosensitive resin to form the contact hole H1 at a predetermined position.

Subsequently, referring to FIG. 3I, a conductive film 18M is formed by, for example, a sputtering method on the insulating film 17. The conductive film 18M serves as the source/drain electrode 18 made of the above-described material or the like. The above-mentioned contact hole H1 is filled with the conductive film 18M. Thereafter, the conductive film 18M is patterned into a predetermined shape by, for example, photolithography and etching. In this way, as illustrated in FIG. 1, the source/drain electrode 18 is formed on the insulating film 17, while the source/drain electrode 18 is electrically connected to the low resistance region 12B of the oxide semiconductor film 12 through the contact hole H1. At this occasion, an electrode that is made of ITO, aluminum including neodymium, or the like and is suitable for an anode of an organic EL element may be preferably formed in an uppermost surface of the source/drain electrode 18. This makes it possible to form a back plane to drive an organic EL display with the extremely small number of processes. With use of the above-described processes, the semiconductor device 1 illustrated in FIG. 1 is completed.

[Workings and Effects of Semiconductor Device 1]

As described above, in the semiconductor device 1, the oxide semiconductor film 12 includes the first region portion 12R1 in the vicinity of the interface IF. The composition ratio of one or more of tin, gallium, and aluminum in the first region portion 12R1 is relatively higher than the composition ratio in other portions. Thus, oxygen permeability in the first region portion 12R1 is kept low. It is therefore possible to prevent oxygen desorption from the channel region 12T, and to restrain a decrease in an effective channel length. This makes it possible for the semiconductor device 1 to exhibit stable operation characteristics.

Also, in the method of manufacturing the semiconductor device 1, in the process illustrated in FIG. 3C, the first region portion 12R1 in the oxide semiconductor film 12 is formed together with formation of the oxide conductive film 15. Specifically, wet etching with the mixed liquid of phosphoric acid, nitric acid, and acetic acid is carried out, to selectively remove the oxide conductive material film 15M1 and simultaneously to lower the composition ratio of indium (In) in the surface of the oxide semiconductor film 12, causing an increase in the composition ratio of a strongly oxidative element such as tin (Sn). Hence, it is possible to manufacture the semiconductor device 1 relatively easily, attaining good manufacturability.

### 2. Modification Example

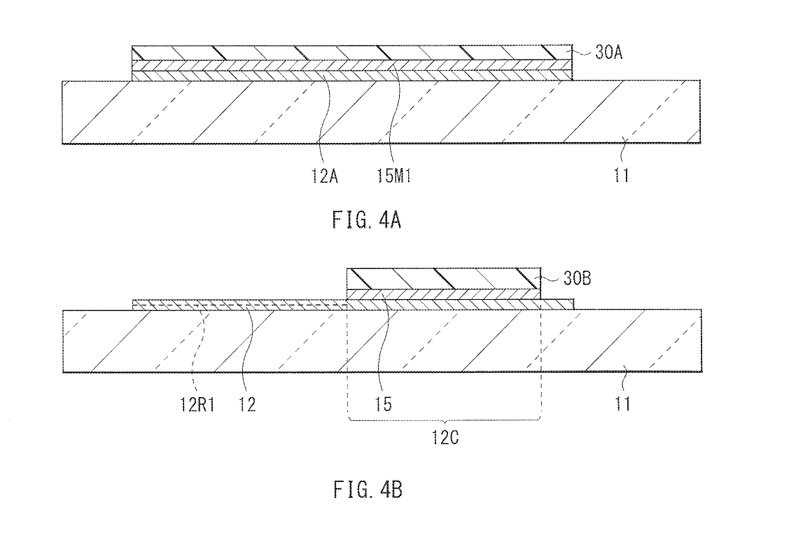

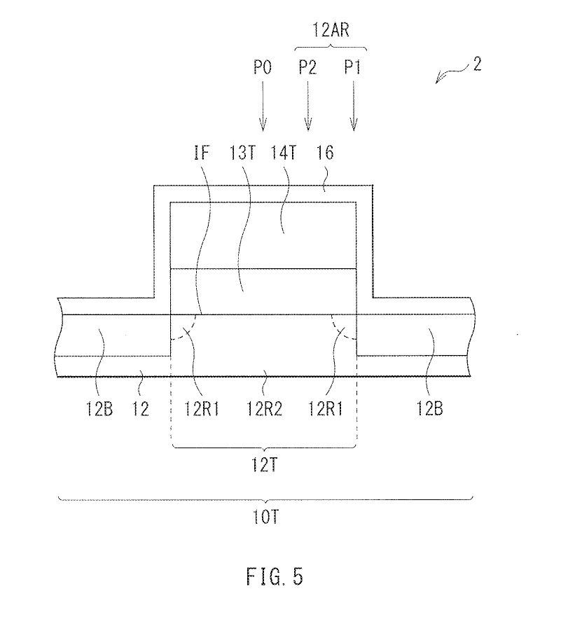

FIGS. 4A and 4B are cross-sectional views illustrating processes in a method of manufacturing the semiconductor device 1 according to a modification example of the above-described example embodiment, In the above-described example embodiment, after forming the semiconductor material film 12M and the oxide conductive material film 15M, a photolithography process is carried out once with use of a half tone mask to form the oxide semiconductor film 12 and the oxide conductive film 15 each having a predetermined shape (refer to FIGS. 3B and 3C). On the other hand, as in the present modification example, photolithography process may be carried out twice.

Specifically, first, referring to FIG. 4A, the semiconductor material film 12M and the oxide conductive material film 15M are patterned in island shapes by first-stage photolithography and wet etching using the resist 30A. Thus, first, the semiconductor material film 12A and the oxide conductive material film 15M1 are obtained. The oxide conductive material film may have a substantially same shape as that of the semiconductor material film 12A. As an etchant at this occasion, for example, dilute hydrofluoric acid may be preferably used. Further, the oxide conductive material film 15M1 is patterned in an island shape by second-stage photolithography and wet etching using the mixed liquid of phosphoric acid, nitric acid, and acetic acid. At this occasion, the oxide conductive material film 15M1 is allowed to remain only in a region in which the retention capacitor 10C is formed. Thus, the oxide conductive film 15 is obtained that is formed in a predetermined region over the oxide semiconductor film 12. Also in the present modification example, it is possible to form the first region portion 12R1 in the vicinity of the surface of the oxide semiconductor film 12 by means of the etching treatment with the mixed liquid of phosphoric acid, nitric acid, and acetic acid in patterning the oxide conductive material film 15M1 in an island shape. It is therefore possible for the present modification example to obtain similar workings and effects to those of the above-described first embodiment.

### 3. Second Embodiment

### Configuration of Semiconductor Device 2

Description will be given on a configuration of a semiconductor device 2 according to a second embodiment of the present disclosure with reference to FIG. 5. In the semiconductor device 1 according to the above-described first embodiment, the first region portion 12R1 in the transistor 10T extends, in an in-plane direction, for example, over the entire channel region 12T of the oxide semiconductor film 12. On the other hand, in the semiconductor device 2, in the oxide semiconductor film 12 occupying the channel region 12T, the first region portion 12R1 is located in vicinity of a periphery of the channel region 12T in the in-plane direction. The term ‘in vicinity of a periphery of the channel region 12T’ as used here refers to a region 12AR extending from a position P2 to an edge P1, in the oxide semiconductor film 12 occupying the channel region 12T. The position P2 is an intermediate position between a center PO in the in-plane direction and the edge P1.

The first region portion 12R1 in the semiconductor device 2 may be formed, for example, by performing etching treatment with the mixed liquid of phosphoric acid, nitric acid, and acetic acid on the vicinity of the periphery of the channel region 12T, after forming the gate insulating film 13T and the gate electrode 14T, and before forming the high resistance film 16.

[Workings and Effects of Semiconductor Device 2]

In the semiconductor device 2 according to the present embodiment, the first region portion 12R1 having low oxygen permeability is provided in the region 12AR in the vicinity of the periphery of the channel region 12T. Thus, oxygen permeability in the first region portion 12R1 is kept low. Hence, it is possible to prevent oxygen desorption from the channel region 12T, restraining a decrease in an effective channel length. This allows the semiconductor device 2 to exhibit stable operation characteristics.

### 4. Third Embodiment

### 4.1. Organic EL (Electroluminescence) Display Unit

[Configuration of Display Unit 3]

(Cross-Sectional Configuration)

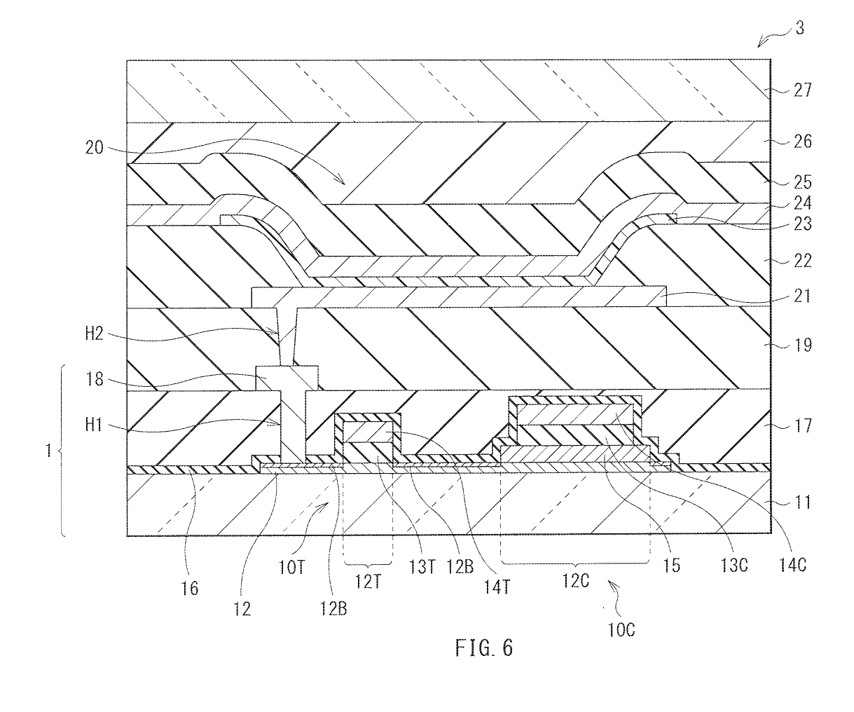

FIG. 6 illustrates a cross-sectional configuration of a display unit 3 including the above-described semiconductor device 1. The display unit 3 may be an active-matrix organic EL (Electroluminescence) display unit, and may include the transistor 10T including the oxide semiconductor film 12 and an organic EL element 20 configured to be driven by the transistor 10T. The transistor 10T and the organic EL element 20 each may be provided in a plurality. FIG. 6 illustrates a region (a subpixel) corresponding to one transistor 10T and one organic EL element 20.

In the display unit 3, the transistor 10T and the retention capacitor 10C may be provided on the substrate 11; and the organic EL element 20 may be provided on the transistor 10T and the retention capacitor 10C with a planarization film 19 in between. The transistor 10T and the retention capacitor 10C constitute the semiconductor device 1 described above in the first embodiment.

The planarization film 19 may extend over the entire display region (the display region 50 in FIG. 7, which will be described later) so as to cover the source/drain electrode 18 and the insulating film 17 of the semiconductor device 1. The planarization film 19 may be configured of, for example, polyimide or an acrylic resin. The planarization film 19 may be provided with a contact hole H2 that goes through the planarization film 19 at a position corresponding to the source/drain electrode 18. The contact hole H2 is configured to connect the source/drain electrode 18 of the transistor 10T and a first electrode 21 of the organic EL element 20.

The organic EL element 20 may be provided on the planarization film 19. The organic EL element 20 may include the first electrode 21, a pixel separation film 22, an organic layer 23, and a second electrode 24 that are stacked in order on the planarization film 19, and may be sealed by a protective film 25. On the protective film 25, a sealing substrate 27 is bonded with an adhesion layer 26 in between. The adhesion layer may be configured of a thermosetting resin or an ultraviolet curing resin. The display unit 3 may be of a bottom emission type (a lower surface emission type) in which light generated in the organic layer 23 is extracted through the substrate 11 side, or of a top emission type (an upper surface emission type) in which the light is extracted through the sealing substrate 27 side.

The first electrode 21 may be provided on the planarization film 19 so as to fill the contact hole H2. The first electrode 21 serves as, for example, an anode, and may be provided for each organic EL element 20. In the display unit 3 of the bottom emission type, the first electrode 21 may be configured of a transparent conductive film. Specifically, the first electrode 21 may be configured of a single-layer film made of one of indium tin oxide (ITO), indium zinc oxide (IZO), indium zinc oxide (InZnO), or the like, or a stacked film of two or more thereof. On the other hand, in the display unit 3 of the top emission type, the first electrode 21 may be configured of a metal having high reflectivity. Specifically, the first electrode 21 may be configured of a single-layer film made of a single substance metal of at least one of aluminum, magnesium (Mg), calcium (Ca), and sodium (Na), or made of an alloy including at least one thereof. The first electrode 21 may be configured of a stacked film in which the single substance metals or the alloys are stacked.

The pixel separation film 22 is configured to provide sufficient insulation between the first electrode 21 and the second electrode 24, and to divide and separate a light emission region of each element. The pixel separation film 22 may be provided with an aperture facing the light emission region of each element. The pixel separation film 22 may be configured of, for example, a photosensitive resin such as, but not limited to, polyimide, an acrylic resin, and a novolac based resin.

The organic layer 23 may be provided so as to cover the apertures of the pixel separation film 22. The organic layer 23 may include an organic electroluminescence layer (an organic EL layer), and is configured to generate light emission by application of a drive current. The organic layer 23 may include, for example, a hole injection layer, a hole transport layer, an organic EL layer, and an electron transport layer in this order from the substrate 11 (the first electrode 21) side. In the organic EL layer, recombination of electrons and holes occurs to generate light. There is no limitation on constituent materials of the organic EL layer, and the organic EL layer may be configured of general low-molecular and high-molecular organic materials. The organic EL layers each configured to emit, for example, red, green, or blue light may be separately formed for each element. Alternatively, the organic EL layer configured to emit white light (for example, a stack of organic EL layers each configured to emit red, green, or blue) may be formed over the entire surface of the substrate 11. The hole injection layer is configured to improve hole injection efficiency and to prevent leaks. The hole transport layer is configured to improve hole transport efficiency to the organic EL layer. Layers except for the organic EL layer, that is, the hole injection layer, the hole transport layer, or the electron transport layer may be provided as necessary.

The second electrode 24 serves as, for example, a cathode, and may be configured of a metal conductive film. In the display unit 3 of the bottom emission type, the second electrode 24 may be configured of a metal having high reflectivity. Specifically, the second electrode 24 may be configured of a single-layer film made of a single substance metal of at least one of aluminum, magnesium (Mg), calcium (Ca), and sodium (Na), or made of an alloy including at least one thereof. The second electrode 24 may be configured of a stacked film in which the single substance metals or the alloys are stacked. On the other hand, in the display unit 3 of the top emission type, the second electrode 24 may be configured of a transparent conductive film such as, but not limited to, ITO and IZO. The second electrode 24 may be provided commonly to the elements in a state in which the second electrode 24 is insulated from the first electrode 21.

The protective film 25 may be configured of either an insulating material or a conductive material. Non-limited examples of insulating materials may include amorphous silicon (a-Si), amorphous silicon carbide (a-SiC), amorphous silicon nitride (a-Si₍ᵢ₋ₓ₎Nₓ), and amorphous carbon (a-C).

The sealing substrate 27 may be disposed so as to face the substrate 11 with the transistor 10T, the retention capacitor 10C, and the organic EL element 20 in between. The sealing substrate 27 may be configured with use of similar materials to those of the above-described substrate 11. In the display unit 3 of the top emission type, a transparent material may be used for the sealing substrate 27, and color filters and light-shielding films may be provided on the sealing substrate 27 side. In the display unit 3 of the bottom emission type, the substrate 11 may be configured of a transparent material, and the color filters and the light-shielding films may be provided on the substrate 11 side.

(Configurations of Peripheral Circuits and Pixel Circuit)

As illustrated in FIG. 7, the display unit 3 may include a plurality of pixels PXLC each including the organic EL element 20. The pixels PXLC may be arrayed, for example, in a matrix in a display region 50 on the substrate 11. Around the display region 50, there may be provided a horizontal selector (HSEL) 51 as a signal line drive circuit, a write scanner (WSCN) 52 as a scan line drive circuit, and a power source scanner (DSCN) 53 as a power line drive circuit.

The display region 50 may include a plurality of (n; n is an integer) signal lines DTL1 to DTLn in a column direction, and a plurality of (m; m is an integer) scan lines WSL1 to WSLm in a row direction. Each of the pixels PXLC may be disposed at an intersection of the signal lines DTL and the scan lines WSL. The pixels PXLC each may be one of the pixels corresponding to R, G, and B. Each of the data lines DTL may be electrically connected to the horizontal selector 51, which is configured to supply each of the pixels PXLC with picture signals through the signal line DTL. Each of the scan lines WSL may be electrically connected to the write scanner 52, which is configured to supply each of the pixels PXLC with scan signals (selection pulses) through the scan line WSL. Each of power lines DSL may be connected to the power source scanner 53, which is configured to supply each of the pixels PXLC with power source signals (control pulses) through the power line DSL.

FIG. 8 illustrates a specific example of a circuit configuration in the pixel PXLC. Each of the pixels PXLC may include a pixel circuit 50A including the organic EL element 20. The pixel circuit 50A may be an active-matrix drive circuit including a sampling transistor Tr1, a drive transistor Tr2, a retention capacitor 10C, and the organic EL element 20. One or both of the sampling transistor Tr1 and the drive transistor Tr2 correspond to the transistor 10T of the above-described example embodiments or the like.

The sampling transistor Tr1 may include a gate, a source, and a drain; the gate may be connected to the associated scan line WSL; one of the source and the drain may be connected to the associated signal line DTL; and the other may be connected to a gate of the drive transistor Tr2. The drive transistor Tr2 may include a gate and a source; the gate may be connected to the associated power line DSL; and the source may be connected to an anode of the organic EL element 20. A cathode of the organic EL element 20 may be connected to a ground wiring 5H. It is to be noted that the ground wiring 5H may be connected commonly to all the pixels PXLC. The retention capacitor 10C may be connected between the source and the gate of the drive transistor Tr2.

The sampling transistor Tr1 is configured to become conductive in response to the scan signal (the selection pulse) supplied from the scan line WSL, to sample a signal potential of the picture signal supplied from the signal line DTL, and to allow the retention capacitor 5C to store the sampled signal potential. The drive transistor Tr2 is configured to receive current supply from the power line DSL that is set to a predetermined first potential (not illustrated), and to supply the organic EL element 20 with a drive current according to the signal potential stored in the retention capacitor 10C. The organic EL element 20 is configured to emit light with intensity according to the signal potential of the picture signal, by means of the drive current supplied from the drive transistor Tr2.

In such a circuit configuration, the sampling transistor Tr1 becomes conductive in response to the scan signal (the selection pulse) supplied from the scan line WSL. Thereby, the signal potential of the picture signal supplied from the signal line DTL is sampled, and the signal potential thus sampled is stored in the retention capacitor 10C. In the meanwhile, the drive transistor Tr2 is supplied with a current from the power line DSL set to the above-mentioned first potential, allowing a drive current to be supplied to the organic EL element 20 (each of the organic EL elements in red, green, and blue) according to the signal potential stored in the retention capacitor 10C. Then, the organic EL elements 20 each emit light with intensity according to the signal potential of the picture signal, by means of the drive current thus supplied. In this way, in the display unit 3, picture display is performed based on the picture signal.

[Method of Manufacturing Display Unit 3]

The display unit 3 may be manufactured, for example, as follows. First, as described above in the first embodiment, the transistor 10T and the retention capacitor 10C in the semiconductor device 1 are formed. Thereafter, the planarization film 19 made of the above-described material is deposited by, for example, a spin coating method or a slit coating method so as to cover the insulating film 17 and the source/drain electrode 18. The contact hole H2 is formed in part of the region facing the source/drain electrode 18.

Subsequently, the organic EL element 20 is formed on the planarization film 19. Specifically, the first electrode 21 made of the above-described material is deposited on the planarization film 19 by, for example, a sputtering method so as to fill the contact hole H2. Then, the first electrode 21 is patterned by photolithography and etching. After this, the pixel separation film 22 having the aperture over the first electrode 21 is formed. Then, the organic layer 23 is deposited by, for example, a vacuum evaporation method. Subsequently, the second electrode 24 made of the above-described material is formed on the organic layer 23 by, for example, a sputtering method. Next, the protective film 25 is deposited on the second electrode 24 by, for example, a CVD method. The sealing substrate 27 is bonded on the protective film 25 using the adhesion layer 26. With the above-described processes, the display unit 3 illustrated in FIG. 6 is completed.

[Operations of Display Unit 3]

In the display unit 3, drive currents according to picture signals of their respective colors are applied to the pixels PXLC each corresponding to one of R, G, and B, for example. Then, electrons and holes are injected in the organic layer 23 through the first electrode 21 and the second electrode 24. The electrons and the holes are recombined in the organic EL layer included in the organic layer 23 to generate light emission. In this way, in the display unit 3, picture display in full color, for example, in R, G, and B is performed. Moreover, in such picture display operation, a potential corresponding to the picture signal is applied to one end of the retention capacitor 10C. Thus, charges corresponding to the picture signal are accumulated between the oxide conductive film 15 and the capacitor electrode 14C.

[Workings and Effects of Display Unit 3]

Since the display unit 3 includes the semiconductor device 1, it is possible to reduce, for example, variation in a signal voltage applied to the organic EL element 20 from the transistor 10T, or variation in a value of a current flowing to the organic EL element 20 from the transistor 10T. This is because a change in an effective channel length due to oxygen desorption in the transistor 10T is restrained. This results in reduction in degradation in image quality such as display unevenness, allowing for good display performance.

### 4.2. Liquid Crystal Display Unit

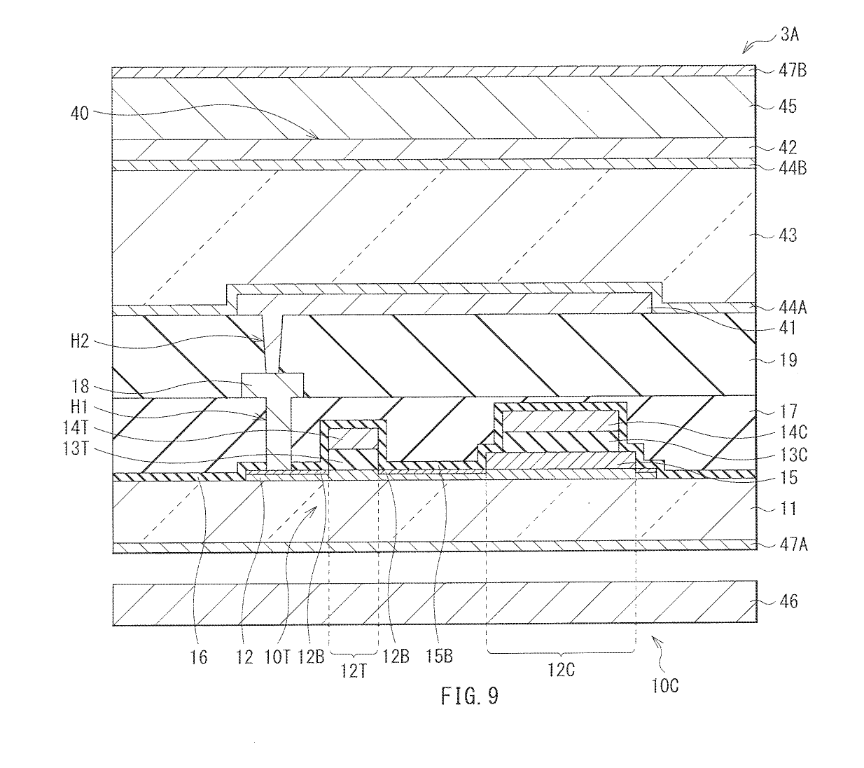

FIG. 9 illustrates a cross-sectional configuration of a display unit 3A according to a modification example 1 of the above-described example embodiment. The display unit 3A includes a liquid crystal display element 40 instead of the organic EL element 20 of the display unit 3. Otherwise, the display unit 3A may have a similar configuration to that of the above-described display unit 3, and may also have similar workings and effects thereto.

The display unit 3A includes the transistor 10T and the retention capacitor 10C similarly to the display unit 3. The liquid crystal display element 40 may be provided in an upper level above the transistor 10T and the retention capacitor 10C with the planarization film 19 in between.

The liquid crystal display element 40 may have a configuration in which a liquid crystal layer 43 is sealed between a pixel electrode 41 and an opposite electrode 42. Orientation films 44A and 44B may be provided on surfaces on the liquid crystal layer 43 side of the pixel electrode 41 and the opposite electrode 43, respectively. The pixel electrode 41 may be provided for each pixel, and may be electrically connected to, for example, the source/drain electrode 18 of the transistor 10T. The opposite electrode 42 may be provided as a common electrode of a plurality of pixels on an opposite substrate 45, and may be maintained at, for example, a common potential. The liquid crystal layer 43 may be configured of liquid crystal driven in, for example, a VA (vertical alignment) mode, a TN (twisted nematic) mode, or an IPS (in plane switching) mode, or the like.

Moreover, a backlight 46 may be disposed below the substrate 11. Polarization plates 47A and 47B may be attached to the substrate 11 on the backlight 46 side and to the opposite substrate 45.

The backlight 46 is a light source configured to emit light toward the liquid crystal layer 43, and may include, for example, a plurality of LEDs (light emitting diodes) or CCFLs (cold cathode fluorescent lamps). The backlight 46 is configured to be controlled between a lighting-on state and a lighting-off state by an undepicetd backlight drive section.

The polarization plates 47A and 47B are disposed in a crossed Nicol state, allowing illumination light from the backlight 46 to be blocked in no-voltage-applied state (an OFF state) and to pass through in a voltage-applied state (an ON state).

The display unit 3A includes the transistor 10T in which the oxide semiconductor film 12 includes the first region portion 12R1, similarly to the display unit 3 according to the above-described example embodiment. Accordingly, a change in an effective channel length due to oxygen desorption from the transistor 10T is restrained. Hence, it is possible to reduce degradation in image quality such as display unevenness, allowing for good display performance.

### 4.3. Electronic Paper

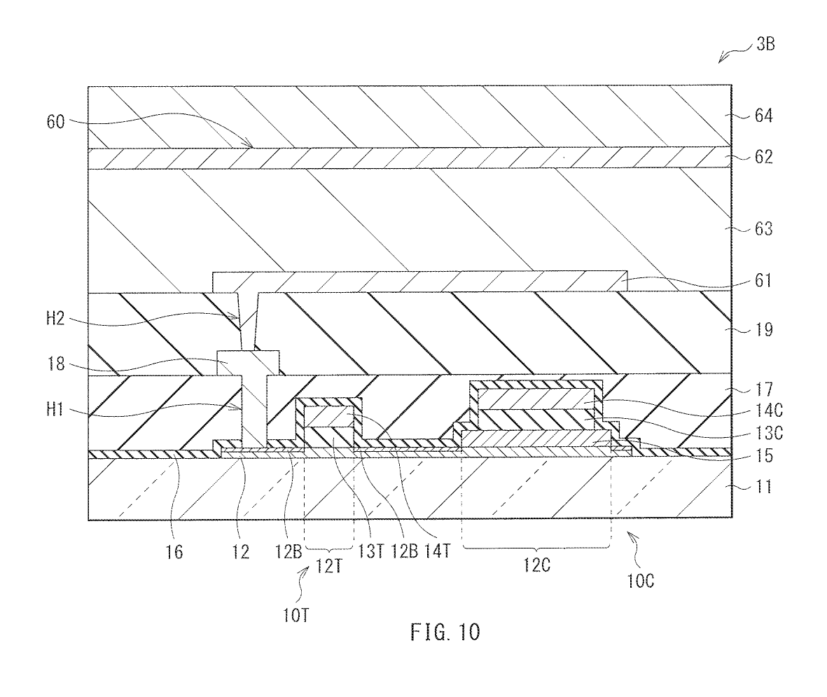

FIG. 10 illustrates a cross-sectional configuration of a display unit 3B according to a modification example 2 of the above-described example embodiment. The display unit 3B is a so-called electronic paper, and includes an electrophoretic display element 60 instead of the organic EL element 20 of the display unit 3. Otherwise, the display unit 3B may have a similar configuration to that of the above-described display unit 3, and may also have similar workings and effects thereto.

The display unit 3B includes the transistor 10T and the retention capacitor 10C similarly to the display unit 3. The electrophoretic display element 60 may be provided in an upper level above the transistor 10T and the retention capacitor 10C with the planarization film 19 in between.

The electrophoretic display element 60 may have a configuration in which a display layer 63 made of an electrophoretic display body is sealed between a pixel electrode 61 and a common electrode 62. The pixel electrode 61 may be provided for each pixel, and may be electrically connected to, for example, the source/drain electrode 18 of the transistor 10T. The common electrode 62 may be provided as a common electrode of a plurality of pixels on an opposite substrate 64.

The display unit 3B includes the transistor 10T in which the oxide semiconductor film 12 includes the first region portion 12R1, similarly to the display unit 3 according to the above-described example embodiment. Accordingly, a change in an effective channel length due to oxygen desorption from the transistor 10T is restrained. Hence, it is possible to reduce degradation in image quality such as display unevenness, allowing for good display performance.

### 5. Application Example

In the following, description will be given on application examples of the above-described display unit (the display units 3, 3A, and 3B) to electronic apparatuses. Non-limited examples of electronic apparatuses may include a television device and a smart phone. The above-described display unit may also be applied to electronic apparatuses in various fields to perform display of images or pictures based on picture signals inputted from outside or picture signals generated inside.

(Module)

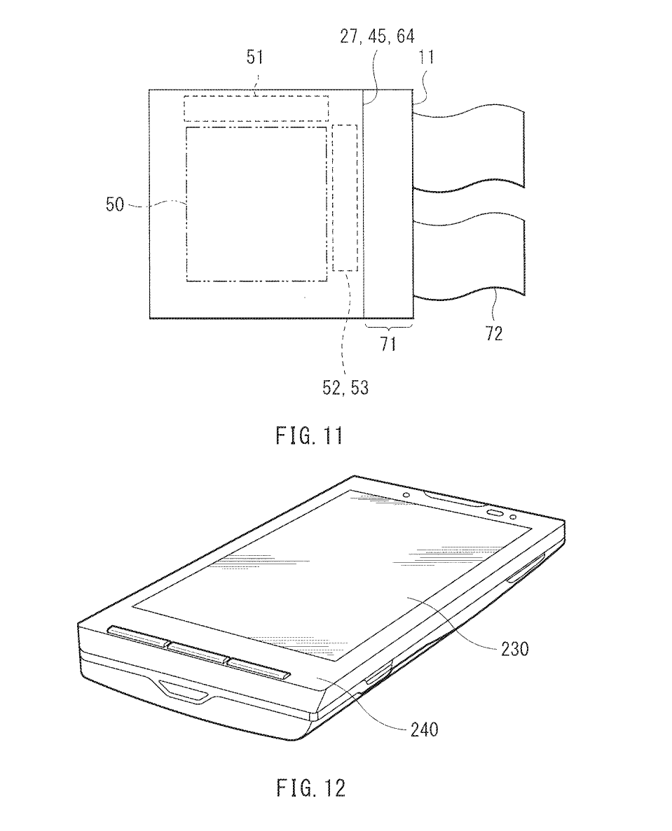

The above-described display unit may be incorporated, in a form of a module as illustrated in FIG. 11, in various electronic apparatuses such as application examples 1 and 2, which will be exemplified below. The module may include, for example, a region 71 exposed beyond the sealing substrate 27 or the opposite substrates 45 and 64, along one side of a substrate 11. In the exposed region 71, there may be provided external connection terminals (not illustrated) that are extended from wirings of the horizontal selector 51, the write scanner 52, and the power source scanner 53. On the external connection terminals, a flexible printed circuit (FPC) 72 for signal input and output may be provided.

### Application Example 1

FIG. 12 illustrates an appearance of a smart phone to which the display unit according to the above-described example embodiment may be applied. The smart phone may include, for example, a display section 230 and a non-display section 240. The display section 230 may be configured of the display unit according to the above-described example embodiment.

### Application Example 2

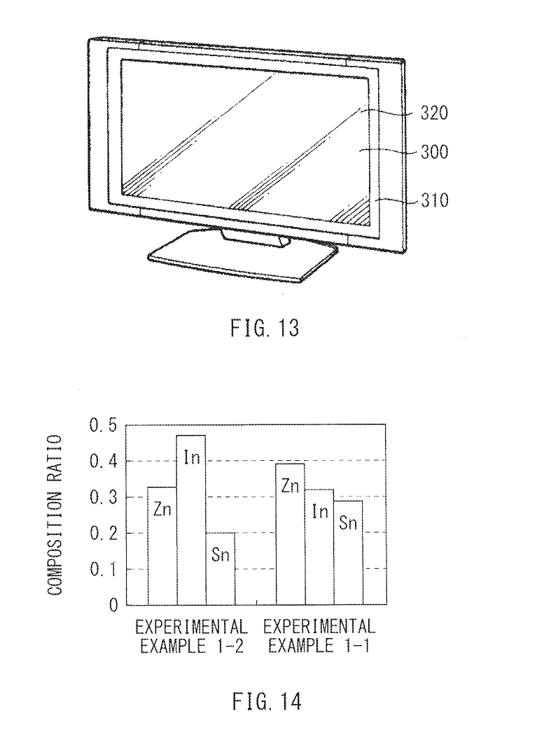

FIG. 13 illustrates an appearance of a television device to which the display unit according to the above-described example embodiment may be applied. The television device may include, for example, a picture display screen section 300 including a front panel 310 and a filter glass 320. The picture display screen section 300 may be configured of the display unit according to the above-described example embodiment.

### 6. Experimental Example

### Experimental Example 1-1

The oxide semiconductor film 12 used in the semiconductor device 1 illustrated in FIG. 1 and so forth was fabricated following the procedure described above in the first embodiment. Specifically, the semiconductor material film 12M made of ITZO was deposited with a thickness of 50 nm over the entire surface of the substrate 11 made of alkali-free glass by sputtering treatment using a ceramic target made of ITZO. Next, wet etching was carried out using the mixed liquid of phosphoric acid, nitric acid, and acetic acid, to form the first region portion 12R1 in the vicinity of the surface of the semiconductor material film 12M. Thus, the oxide semiconductor film 12 was obtained.

### Experimental Example 1-2

The oxide semiconductor film 12 was fabricated in a similar manner to the experimental example 1-1, except that no wet etching with the mixed liquid of phosphoric acid, nitric acid, and acetic acid was carried out.

FIG. 14 illustrates comparison between the composition ratios in the surfaces of the oxide semiconductor films 12 of the experimental examples 1-1 and 1-2. It is to be noted that surface element analysis was carried out by X-ray photoelectron spectroscopy (XPS). As found in FIG. 14, it was confirmed that wet etching using the mixed liquid of phosphoric acid, nitric acid, and acetic acid resulted in a decrease in the composition ratio of indium in the vicinity of the surface of the oxide semiconductor film 12, and an increase in the composition ratio of tin.

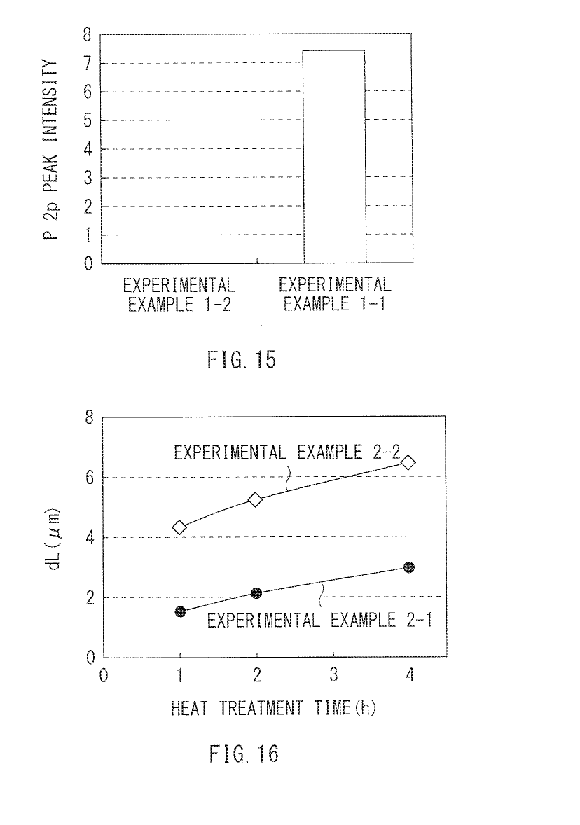

FIG. 15 illustrates comparison between 2 p peak intensity of phosphorus (P) (by means of XPS) in the surfaces of the oxide semiconductor films 12 of the experimental examples 1-1 and 1-2. According to FIG. 15, in the experimental example 1-1 in which wet etching with the mixed liquid of phosphoric acid, nitric acid, and acetic acid was carried out, a 2 p peak of phosphorus (P) was observed. In the experimental example 1-2 in which no such wet etching was carried out, no such peak was observed. Based on these results, it was confirmed that phosphorus remains in the vicinity of the surface of the oxide semiconductor film 12 when the first region portion 12R1 was formed in the oxide semiconductor film 12 by wet etching using phosphoric acid.

### Experimental Example 2-1

Next, a sample of the semiconductor device 1 illustrated in FIG. 1 and so forth was fabricated following the procedure described above in the first embodiment. Specifically, as illustrated in FIG. 3A, the semiconductor material film 12M made of ITZO was deposited with a thickness of 50 nm over the entire surface of the substrate 11 made of alkali-free glass by sputtering treatment using a ceramic target made of ITZO. Thereafter, the oxide conductive material film 15M was deposited with a thickness of 50 nm over the entire surface of the semiconductor material film 12M by a sputtering method. The oxide conductive material film 15M was made of IZO having conductivity of 1×10² S/cm. Next, a stacked structure of the semiconductor material film 12A and the oxide conductive material film 15M having a same shape in planar view was formed by photolithography. After this, as illustrated in FIG. 3C, photolithography and wet etching using the mixed liquid of phosphoric acid, nitric acid, and acetic acid were carried out to form the oxide semiconductor film 12 and the oxide conductive film 15 each having a predetermined shape. Further, as illustrated in FIG. 3E, the gate insulating film 13T, the gate electrode 14T, the capacitor insulating film 13C, and the capacitor electrode 14C were formed at predetermined positions. Then, as illustrated in FIG. 3F, the metal film 16A made of aluminum was formed so as to cover the entirety. Next, heat treatment was carried out in an oxygen atmosphere at a temperature of about 200° C. to oxidize the metal film 16A. Thus, as illustrated in FIG. 3G, the high resistance film 16 was formed. After forming the high resistance film 16, as illustrated in FIG. 3G, the insulating film 17 was formed over the entire surface of the high resistance film 16. Polyimide was used for the insulating film 17. Subsequently, as illustrated in FIG. 3H, the exposure and development processes were carried out to form the contact hole H1 that goes through the insulating film 17 and the high resistance film 16 at a predetermined position. Next, as illustrated in FIG. 3I, the conductive film 18M that served as the source/drain electrode 18 was formed by a sputtering method on the insulating film 17. The conductive film 18M was made of a stack of molybdenum and Al—Nd. The above-mentioned contact hole H1 was filled with the conductive film 18M. Thereafter, the conductive film 18M was patterned into a predetermined shape by photolithography and etching. Thus, the source/drain electrode 18 was formed on the insulating film 17, while the source/drain electrode 18 was electrically connected to the low resistance region 12B of the oxide semiconductor film 12 through the contact hole H1. Further, heat treatment was carried out in an oxygen atmosphere at a temperature of 270° C. Here, heat treatment time was changed to 1 hour, 2 hours, and 4 hours.

### Experimental Example 2-2

A sample of the semiconductor device 1 was fabricated in a similar manner to the experimental example 2-1, except that the oxide semiconductor film 12 was not subjected to wet etching with the mixed liquid of phosphoric acid, nitric acid, and acetic acid.

FIG. 16 illustrates relation between the heat treatment time and an amount of change in an effective channel length, examined concerning the experimental examples 2-1 and 2-2. Extraction of the amount of change in the effective channel length dL was carried out using a channel resistance method based on channel length dependency of an Id-Vg characteristic obtained with Vd=0.1V. As found in FIG. 16, in the experimental example 2-1 in which the oxide semiconductor film 12 included the first region portion 12R1 having a low indium composition ratio and a high tin composition ratio, the amount of change in the effective channel length dL was suppressed, as compared to that of the experimental example 2-2 in which the oxide semiconductor film 12 did not include the first region portion 12R1.

As demonstrated above in the results of the experimental examples, it was confirmed that, according to the embodiments of the present technology, it was possible to obtain a display unit having high display quality and having reduced display unevenness.

Although description of the present technology has been made by giving the example embodiments and modification examples as mentioned above, the contents of the present technology are not limited to the above-mentioned example embodiments and so forth and may be modified in a variety of ways. For example, a material and a thickness of each layer as described in the above-mentioned example embodiments are not limitative, but other materials and other thicknesses may be adopted.

Moreover, in the above-described example embodiments and so forth, wet etching using the mixed liquid of phosphoric acid, nitric acid, and acetic acid is carried out in forming the first region portion 12R1 in the oxide semiconductor 12. However, the first region portion 12R1 may be formed as a stacked film by, for example, an ion implantation method or a sputtering method.

Furthermore, in the above-described example embodiments and so forth, description has been given on an example of a structure with the high resistance film 16. However, the high resistance film 16 may be removed after forming the low resistance region 12B. It is to be noted that the high resistance film 16 may be preferably formed in order to keep electrical characteristics of the transistor 10T and the retention capacitor 10C stable, as described above.

Also, in the above-described example embodiments and so forth, description has been given on a case in which the low resistance region 12B is provided in part in the thickwise direction, extending from the surface (the upper surface) of the region except for the channel region 12T of the oxide semiconductor film 12. However, the low resistance region 12B may be formed in all in the thickwise direction, extending from the surface (the upper surface) of the oxide semiconductor film 12.

In addition, in the above-described example embodiments and so forth, description has been given on specific configurations of the organic EL element 20, the liquid crystal display element 40, and the electrophoretic display element 60, the transistor 10T, and the retention capacitor 10C. However, some of the components disclosed may be omitted, or another component or other components may be further included.

Also, in addition, the present technology may be applied to display units using other display elements such as, but not limited to, inorganic electroluminescence elements, as well as the organic EL element 20, the liquid crystal display element 40, and the electrophoretic display element 60.

Furthermore, in the above-described example embodiments and so forth, description has been given on a case of an active-matrix display unit. However, the present technology may be applicable to a passive-matrix display unit. In addition, a configuration of the pixel drive circuit for active-matrix driving is not limited to as exemplified in the above-described example embodiments. A capacitor or a transistor may be added as necessary.

It is to be noted that effects described in the specification are merely exemplified and not limited thereto, and effects of the present disclosure may be other effects or may further include other effects. It is possible to achieve at least the following configurations from the above-described example embodiments of the disclosure.

(1)

A semiconductor device, including a transistor in which an oxide semiconductor film, a gate insulating film, and a gate electrode are stacked in order, the oxide semiconductor film including a first region portion and a second region portion,

wherein the oxide semiconductor film includes indium (In), zinc (Zn), and one or more of tin (Sn), gallium (Ga), and aluminum (Al),

the first region portion is located, in a thickwise direction, in vicinity of an interface between the oxide semiconductor film and the gate insulating film, in the oxide semiconductor film, and

a composition ratio of the one or more of tin, gallium, and aluminum in the first region portion is higher than a composition ratio of the one or more of tin, gallium, and aluminum in the second region portion.

(2)

The semiconductor device according to (1),

wherein the oxide semiconductor film includes a channel region that forms the interface between the oxide semiconductor film and the gate insulating film, and the first region portion extends over the channel region in an in-plane direction.

(3)

The semiconductor device according to (1),

wherein the oxide semiconductor film includes a channel region that forms the interface between the oxide semiconductor film and the gate insulating film, and

the first region portion is located in vicinity of a periphery of the channel region in an in-plane direction.

(4)

The semiconductor device according to any one of (1) to (3),

wherein a composition ratio of indium in the first region portion is lower than a composition ratio of indium in the second region portion.

(5)

The semiconductor device according to any one of (1) to (4), further including a substrate and a retention capacitor,

wherein the transistor and the retention capacitor are provided on the substrate.

(6)

The semiconductor device according to (4),

wherein the transistor includes the oxide semiconductor film, the gate insulating film, and the gate electrode stacked in order over a region of the substrate, and

the retention capacitor includes the oxide semiconductor film, a first conductive film, an insulating film, and a second conductive film stacked in order over another region of the substrate.

(7)

The semiconductor device according to any one of (1) to (6), wherein the oxide semiconductor film includes

a channel region and a pair of low resistance regions, the channel region forming the interface between the oxide semiconductor film and the gate insulating film, and the pair of low resistance regions being located adjacent to the channel region and having lower resistance than resistance of the channel region.

(8)

The semiconductor device according to any one of (1) to (7),

wherein the first region portion includes phosphorus (P).

(9)

A method of manufacturing a semiconductor device, including:

forming, on a substrate, an oxide semiconductor film including indium (In), zinc (Zn), and one or more of tin (Sn), gallium (Ga), and aluminum (Al); and

stacking a gate insulating film and a gate electrode in order on the oxide semiconductor film to form a transistor, after increasing a composition ratio of the one or more of tin, gallium, and aluminum in vicinity of an upper surface of the oxide semiconductor film.

(10)

The method of manufacturing the semiconductor device according to (9),

wherein the composition ratio of the one or more of tin, gallium, and aluminum is increased by removing part of indium in the vicinity of the upper surface of the oxide semiconductor film.

(11)

The method of manufacturing the semiconductor device according to (10),

wherein etching treatment is performed on the upper surface of the oxide semiconductor film to remove part of indium in the vicinity of the upper surface of the oxide semiconductor film.

(12)

The method of manufacturing the semiconductor device according to (11),

wherein the etching treatment is performed with an etchant including phosphoric acid.

(13)

A display unit provided with a display element and a semiconductor device configured to drive the display element, the semiconductor device including a transistor in which an oxide semiconductor film, a gate insulating film, and a gate electrode are stacked in order, the oxide semiconductor film including a first region portion and a second region portion,

wherein the oxide semiconductor film includes indium (In), zinc (Zn), and one or more of tin (Sn), gallium (Ga), and aluminum (Al),

the first region portion is located, in a thickwise direction, in vicinity of an interface between the oxide semiconductor film and the gate insulating film, in the oxide semiconductor film, and

a composition ratio of the one or more of tin, gallium, and aluminum in the first region portion is higher than a composition ratio of the one or more of tin, gallium, and aluminum in the second region portion.

(14)

An electronic apparatus provided with a display unit including a display element and a semiconductor device configured to drive the display element, the semiconductor device including a transistor in which an oxide semiconductor film, a gate insulating film, and a gate electrode are stacked in order, the oxide semiconductor film including a first region portion and a second region portion,

wherein the oxide semiconductor film includes indium (In), zinc (Zn), and one or more of tin (Sn), gallium (Ga), and aluminum (Al),

the first region portion is located, in a thickwise direction, in vicinity of an interface between the oxide semiconductor film and the gate insulating film, in the oxide semiconductor film, and

a composition ratio of the one or more of tin, gallium, and aluminum in the first region portion is higher than a composition ratio of the one or more of tin, gallium, and aluminum in the second region portion.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device, comprising a transistor in which an oxide semiconductor film, a gate insulating film, and a gate electrode are stacked in order, the oxide semiconductor film including a first region portion and a second region portion,
wherein the oxide semiconductor film includes indium (In), zinc (Zn), and one or more of tin (Sn), gallium (Ga), and aluminum (Al),
the first region portion is located, in a thickwise direction, in vicinity of an interface between the oxide semiconductor film and the gate insulating film, in the oxide semiconductor film, and
a composition ratio of the one or more of tin, gallium, and aluminum in the first region portion is higher than a composition ratio of the one or more of tin, gallium, and aluminum in the second region portion.

2. The semiconductor device according to claim 1,
wherein the oxide semiconductor film includes a channel region that forms the interface between the oxide semiconductor film and the gate insulating film, and
the first region portion extends over the channel region in an in-plane direction.

3. The semiconductor device according to claim 1,
wherein the oxide semiconductor film includes a channel region that forms the interface between the oxide semiconductor film and the gate insulating film, and
the first region portion is located in vicinity of a periphery of the channel region in an in-plane direction.

4. The semiconductor device according to claim 1,
wherein a composition ratio of indium in the first region portion is lower than a composition ratio of indium in the second region portion.

5. The semiconductor device according to claim 1, further comprising a substrate and a retention capacitor,
wherein the transistor and the retention capacitor are provided on the substrate.

6. The semiconductor device according to claim 4,
wherein the transistor includes the oxide semiconductor film, the gate insulating film, and the gate electrode stacked in order over a region of the substrate, and
the retention capacitor includes the oxide semiconductor film, a first conductive film, an insulating film, and a second conductive film stacked in order over another region of the substrate.

7. The semiconductor device according to claim 1, wherein the oxide semiconductor film includes
a channel region and a pair of low resistance regions, the channel region forming the interface between the oxide semiconductor film and the gate insulating film, and the pair of low resistance regions being located adjacent to the channel region and having lower resistance than resistance of the channel region.

8. The semiconductor device according to claim 1,
wherein the first region portion includes phosphorus (P).

9. A method of manufacturing a semiconductor device, comprising:
forming, on a substrate, an oxide semiconductor film including indium (In), zinc (Zn), and one or more of tin (Sn), gallium (Ga), and aluminum (Al); and
stacking a gate insulating film and a gate electrode in order on the oxide semiconductor film to form a transistor, after increasing a composition ratio of the one or more of tin, gallium, and aluminum in vicinity of an upper surface of the oxide semiconductor film.

10. The method of manufacturing the semiconductor device according to claim 9,
wherein the composition ratio of the one or more of tin, gallium, and aluminum is increased by removing part of indium in the vicinity of the upper surface of the oxide semiconductor film.

11. The method of manufacturing the semiconductor device according to claim 10,
wherein etching treatment is performed on the upper surface of the oxide semiconductor film to remove part of indium in the vicinity of the upper surface of the oxide semiconductor film.

12. The method of manufacturing the semiconductor device according to claim 11,
wherein the etching treatment is performed with an etchant including phosphoric acid.

13. A display unit provided with a display element and a semiconductor device configured to drive the display element, the semiconductor device comprising a transistor in which an oxide semiconductor film, a gate insulating film, and a gate electrode are stacked in order, the oxide semiconductor film including a first region portion and a second region portion,
wherein the oxide semiconductor film includes indium (In), zinc (Zn), and one or more of tin (Sn), gallium (Ga), and aluminum (Al),
the first region portion is located, in a thickwise direction, in vicinity of an interface between the oxide semiconductor film and the gate insulating film, in the oxide semiconductor film, and
a composition ratio of the one or more of tin, gallium, and aluminum in the first region portion is higher than a composition ratio of the one or more of tin, gallium, and aluminum in the second region portion.

14. An electronic apparatus provided with a display unit including a display element and a semiconductor device configured to drive the display element, the semiconductor device comprising a transistor in which an oxide semiconductor film, a gate insulating film, and a gate electrode are stacked in order, the oxide semiconductor film including a first region portion and a second region portion,
wherein the oxide semiconductor film includes indium (In), zinc (Zn), and one or more of tin (Sn), gallium (Ga), and aluminum (Al),
the first region portion is located, in a thickwise direction, in vicinity of an interface between the oxide semiconductor film and the gate insulating film, in the oxide semiconductor film, and
a composition ratio of the one or more of tin, gallium, and aluminum in the first region portion is higher than a composition ratio of the one or more of tin, gallium, and aluminum in the second region portion.
